(19) United States
(12) Patent Application Publication
(10) Pub. No.: US 2014/0361272 A1
(43) Pub. Date: Dec. 11, 2014

(54) LIGHT EMITTING ELEMENT, ORGANIC LIGHT EMITTING DISPLAY DEVICE HAVING THE SAME AND METHOD OF MANUFACTURING THE SAME

(71) Applicant: Samsung Display Co., LTD., Yongin-City (KR)

(72) Inventors: Young-Cheol JOO, Hwaseong-si (KR); Soo-Jin PARK, Seoul (KR)

(73) Assignee: Samsung Display Co., LTD., Yongin-City (KR)

(21) Appl. No.: 14/291,806

(22) Filed: May 30, 2014

(30) Foreign Application Priority Data
Jun. 7, 2013 (KR) 10-2013-0065196

(51) Int. Cl. H01L 27/32; H01L 51/00; H01L 51/50

(52) U.S. Cl. CPC H01L 27/3251; H01L 51/5056; H01L 51/5072; H01L 51/5088; H01L 51/5092; H01L 51/0054
USPC 257/40; 438/23

(57) ABSTRACT

A light emitting element includes: a first electrode, a hole injection layer disposed on the first electrode; a hole transport layer disposed on the hole injection layer; a light emitting layer disposed on the hole transport layer, where the light emitting layer includes a light emission host and a light emission dopant; an electron transport layer disposed on the light emitting layer; an electron injection layer disposed on the electron transport layer; and a second electrode disposed on the electron injection layer.

This application claims priority to Korean Patent Applications No. 10-2013-0065196, filed on Jun. 7, 2013, and all the benefits accruing therefrom under 35 U.S.C. §119, the content of which in its entirety is herein incorporated by reference.

### BACKGROUND

1. Technical Field

Exemplary embodiments relate to a light emitting element, an organic light emitting display device including the light emitting element and a method of manufacturing the organic light emitting display device including the light emitting element. More particularly, embodiments of the invention relate to a light emitting element having improved hole injection properties, an organic light emitting display device including the light emitting element and a method of manufacturing the organic light emitting display device including the light emitting element.

2. Description of the Related Art

An organic light emitting display device is an active type flat display to implement images using an organic light emitting diode that generates light therefrom. The organic light emitting display device typically has a slim thickness, light weight and low power consumption, advanced color reproduction and high-definition images due to fast response time.

Generally, the organic light emitting display device includes a light emitting element including two electrodes and a light emitting layer interposed between the two electrodes. In the organic light emitting display device, the organic light emitting display device may include a hole injection layer, a hole transport layer, an electron transport layer and an electron injection layer, on the upper side or underside of the light emitting layer to improve luminance and to reduce consumption power.

The organic light emitting display device is typically driven by electrons and holes, which are provided from two electrodes and form excitons by recombination in the light emitting layer. In the organic light emitting display device, the excitons generate some energy by transition to ground state, and the energy emits a light having specific wavelength. The light having the specific wavelength defines a pixel, and the light of each pixel collectively implements an image. However, the mobility of the electrons and the mobility of the holes may be different from each other, and the injection properties of the electrons and holes may also be different from each other. Because of the differences, the excitons may be accumulated in some boundary between the light emitting layer and the hole injection layer, and quenching may occur by the accumulated excitons. The quenching means an effect of non-light emission, and the non-light emission quenching decreases luminous efficiency of the organic light emitting display device. In particular, the quenching is frequently occurred in a green light emitting layer. In the organic light emitting display device, a higher voltage may be applied to the two electrodes to increase the mobility of the holes, and to reduce the accumulation of the excitons in the boundary between the hole transport layer and the light emitting layer, while a driving voltage may be increased when the higher voltage is applied to the two electrodes.

### SUMMARY

Exemplary embodiments of the invention relate to a light emitting element having high luminous efficiency and long lifetime by reducing non-light emission quenching of electrons and holes in the boundary between a hole injection layer and a light emitting layer thereof.

Exemplary embodiments of the invention also relate to an organic light emitting display device including light emitting element, and a method of manufacturing the organic light emitting display device including the light emitting element.

According to an exemplary embodiment, a light emitting element includes: a first electrode, a hole injection layer disposed on the first electrode; a hole transport layer disposed on the hole injection layer; a light emitting layer disposed on the hole transport layer, where the light emitting layer includes a light emission host and a light emission dopant; an electron transport layer disposed on the light emitting layer; an electron injection layer disposed on the electron transport layer; and a second electrode disposed on the electron injection layer.

In an exemplary embodiment, the light emission host and the light emission dopant of the light emitting layer may be in a weight ratio of about 85:15 to about 90:10.

In an exemplary embodiment, the light emitting layer may have a thickness in a range of about 30 nanometers (nm) to about 50 nanometers (nm).

In an exemplary embodiment, the light emitting element may further include a host layer disposed between the hole transport layer and the light emitting layer, where the host layer includes the light emission host.

In an exemplary embodiment, the light emitting element may further include a first intermediate layer disposed between the first electrode and the hole injection layer, where the first intermediate layer may include a pyrazine compound.

In an exemplary embodiment, the pyrazine compound of the first intermediate layer may include a hexaazatriphenylene compound.

In an exemplary embodiment, the light emitting element may further include a second intermediate layer disposed between the hole injection layer and hole transport layer.

In an exemplary embodiment, the second intermediate layer may include a hole injection material of the hole injection layer and a hole transport material of the hole transport layer.

In an exemplary embodiment, the light emitting element may further include a third intermediate layer disposed between the hole transport layer and the light emitting layer, where the third intermediate layer may include the pyrazine compound.

In an exemplary embodiment, the pyrazine compound of the third intermediate layer may include hexaazatriphenylene compound.

In such an embodiment, the light emitting element includes the host layer that does not include a light emission dopant such that the non-light emission quenching the light emitting element may be minimized by effectively preventing the accumulation of excitons in the boundary of the hole transport layer. In such an embodiment, the light emitting element may decrease driving voltage, and may improve hole injection properties, by including the first intermediate layer, the second intermediate layer and the third intermediate layer.

According to another exemplary embodiment, an organic light emitting display device includes: a base substrate; a light emitting element disposed on the base substrate, where the light emitting element includes: a first electrode; a light emitting layer disposed on the first electrode, where the light emitting layer includes a light emission host and a light emission dopant; and a second electrode disposed on the light emitting layer; a thin film transistor disposed on the base substrate, where the thin film transistor is electrically connected to the first electrode of the light emitting element; and a protective layer disposed on the second electrode of the light emitting element, where the base substrate and the protective layer encapsulate the thin film transistor and the light emitting element.

In some exemplary embodiments, the light emitting layer of the light emitting element may have a thickness in a range of about 30 nm to about 50 nm, and the light emission host and the light emission dopant of the light emitting layer of the light emitting element may be in a weight ratio of about 85:15 to about 90:10.

In an exemplary embodiment, the light emitting element may further includes: a hole injection layer disposed on the first electrode; a hole transport layer disposed on the hole injection layer; a first intermediate layer disposed between the first electrode and the hole injection layer, where the first intermediate layer may include a pyrazine compound; a second intermediate layer disposed between the hole injection layer and the hole transport layer, where the second intermediate layer may include a hole injection material and a hole transport material; a third intermediate layer disposed on the hole transport layer, where the third intermediate layer includes the pyrazine compound; and a host layer disposed on the third intermediate layer, where the host layer may include the light emission host.

In such an embodiment, the organic light emitting display device displays high-definition images using low power with improved lifetime. In such an embodiment, the luminous efficiency of the organic light emitting display device may be substantially improved by including light emitting element, in which quenching is substantially reduced or effectively prevented.

According to another exemplary embodiment, a method of manufacturing an organic light emitting display device includes providing a thin film transistor on a base substrate of the organic light emitting display device; providing a first electrode electrically connected to the thin film transistor; providing a hole injection layer on the first electrode; providing a hole transport layer on the hole injection layer; providing a light emitting layer on the hole transport layer, where the light emitting layer includes a light emission host and a light emission dopant; providing an electron transport layer on the light emitting layer; providing an electron injection layer on the electron transport layer; and providing a second electrode on the electron injection layer.

In an exemplary embodiment of the method of manufacturing the organic light emitting display device, the light emitting layer may be formed with the light emission host and the light emission dopant, by a weight ratio of about 85:15 to about 90:10, and the light emitting layer may have a thickness in a range of about 30 nm to about 50 nm.

In an exemplary embodiment of the method of manufacturing the organic light emitting display device, the method may further include providing a first intermediate layer on the first electrode, using the pyrazine compound, where the hole injection layer may be provided on the first intermediate layer.

In an exemplary embodiment of the method of manufacturing the organic light emitting display device, the pyrazine compound of the first intermediate layer may include a hexaazatriphenylene compound.

In an exemplary embodiment of the method of manufacturing the organic light emitting display device, the method may further include providing a second intermediate layer on the hole injection layer, where the hole transport layer may be provided on the second intermediate layer.

In an exemplary embodiment of the method of manufacturing the organic light emitting display device, the providing the second intermediate layer on the hole injection layer may include performing co-deposition or co-sputtering using a hole injection material of the hole injection layer and a hole transport material of the hole transport layer.

In an exemplary embodiment of the method of manufacturing the organic light emitting display device, the providing the second intermediate layer on the hole injection layer may include using a mixture of a hole injection material of the hole injection layer and a hole transport material of the hole transport layer.

In an exemplary embodiment of the method of manufacturing the organic light emitting display device, the method may further include providing a third intermediate layer on the hole transport layer, using the pyrazine compound, where the light emitting layer may be provided on the third intermediate layer.

In an exemplary embodiment of the method of manufacturing the organic light emitting display device, the pyrazine compound of the third intermediate layer may include a hexaazatriphenylene compound.

In an exemplary embodiment of the method of manufacturing the organic light emitting display device, the method may further include providing a host layer on the third intermediate layer using the light emission host, where the light emitting layer may be provided on the host layer.

According to exemplary embodiments of the method of manufacturing the organic light emitting display device, the organic light emitting display having improved hole injection properties is manufactured, and the manufactured organic light emitting display has long lifetime and improved luminous efficiency.

### BRIEF DESCRIPTION OF THE DRAWINGS

The above and other features of the invention will become more apparent by describing in detail exemplary embodiments thereof with reference to the attached drawings, in which:

FIG. 1 is a cross-sectional view illustrating an exemplary embodiment of an organic light emitting display device in accordance with the invention;

FIG. 2 is a cross-sectional view illustrating an exemplary embodiment of a light emitting element of the organic light emitting display device of FIG. 1;

FIG. 3 is a cross-sectional view illustrating an alternative exemplary embodiment of an organic light emitting display device in accordance with the invention;

FIG. 4 is a cross-sectional view illustrating an exemplary embodiment of a light emitting element of the organic light emitting display device of FIG. 3; and

FIGS. 5A to 5G are cross-sectional views illustrating an exemplary embodiment of a method of manufacturing the organic light emitting display device in accordance with the invention.

### DETAILED DESCRIPTION OF THE EMBODIMENTS

Various exemplary embodiments will be described more fully hereinafter with reference to the accompanying drawings, in which some exemplary embodiments are shown. The invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

The terminology used herein is for the purpose of describing particular exemplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims set forth herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments of the invention will be described in further detail with reference to the accompanying drawings.

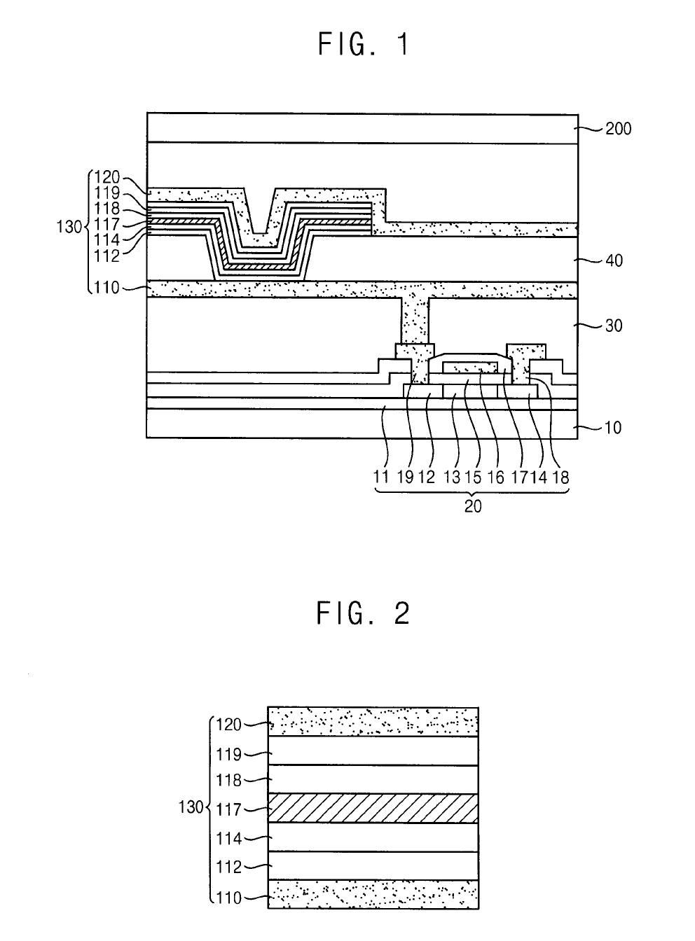

FIG. 1 is a cross-sectional view illustrating an exemplary embodiment of an organic light emitting display device in accordance with the invention.

Referring to FIG. 1, an organic light emitting display device includes a base substrate 10, a thin film transistor 20, an insulation layer 30 that covers the thin film transistor 20, a light emitting element 130 and a protective layer 200 that encapsulates the base substrate 10, the thin film transistor 20, the insulation layer 30 and the light emitting element 130. In an exemplary embodiment, the organic light emitting display device may further include a pixel definition layer 40 disposed on the insulation layer 30. Each elements of the organic light emitting display device will be described in detail hereinafter.

The base substrate 10 may be an inorganic substrate including a glass or poly-silicon. In an exemplary embodiment, the base substrate 10 may be a plastic substrate including a polyethylene terephthalate (“PET”), a polyethylene naphthalate (“PEN”), a polyimide, for example. In an exemplary embodiment, the base substrate 10 may be a flexible substrate including a metal or a polymer having flexibility.

The thin film transistor 20 is disposed between the base substrate 10 and the light emitting element 130, and functions as a switching device that controls or transports a signal to the light emitting element 130. The thin film transistor 20 may include a buffer layer 11, a semiconductor layer 12, 13 and 14, a gate insulation layer 15, a gate electrode 16, an insulating interlayer 17, a source electrode 18 and a drain electrode 19.

The buffer layer 11 blocks impurities diffused from the base substrate 10, and the buffer layer 11 effectively planarizes or improves a flatness of the base substrate 10, and the buffer layer 11 relieves a stress on the base substrate 10 that may occur during a process of providing the thin film transistor 20 on the base substrate 10. In such an embodiment, the buffer layer 11 may include at least one of an oxide, a nitride and an oxynitride, for example. In one exemplary embodiment, for example, the buffer layer 11 may have a single-layered or multi-layered structure including a silicon oxide (SiOx), a silicon nitride (SiNx) and/or a silicon oxynitride (SiOxNy).

In an exemplary embodiment, the semiconductor layer 12, 13 and 14 is disposed on the buffer layer 11 and includes a first impurity area 12, a channel area 13 and a second impurity area 14. Each of the first impurity area 12 and the second impurity area 14 may function as a source area or a drain area. The semiconductor layer 12, 13 and 14 may include a poly-silicon, a poly-silicon having an impurity, an amorphous silicon, an amorphous silicon having an impurity, or a combination thereof.

In an exemplary embodiment, the gate insulation layer 15 may include an oxide or an organic insulating material. In one exemplary embodiment, for example, the gate insulation layer 15 may include at least one of a silicon oxide, a hafnium oxide (HfOx), an aluminum oxide (AlOx), a zirconium oxide (ZrOx), a titanium oxide (TiOx), a tantalum oxide (TiOx), a benzo-cyclo-butene-based resin, an acryl-based resin, etc. The gate insulation layer 15 may have a single-layered or multi-layered structure including the oxide or the organic insulating material.

The gate electrode 16 is disposed on the gate insulation layer 15 substantially close to the semiconductor layer 12, 13 and 14. In one exemplary embodiment, for example, the gate electrode 16 may be disposed on a portion of the gate insulation layer 15, which overlaps the channel 13 of semiconductor layer 12, 13 and 14. In an exemplary embodiment, the gate electrode 16 may include a metal, a metal nitride, a conductive metal oxide, a transparent conductive material, etc. In one exemplary embodiment, for example, the gate electrode 16 may include at least one of an aluminum (Al), an aluminum alloy, an aluminum nitride (AlNx), a silver (Ag), a silver alloy, a tungsten (W), a tungsten nitride (WNx), a copper (Cu), a copper alloy, a nickel (Ni), a chrome (Cr), a molybdenum (Mo), a molybdenum alloy, a titanium (Ti), a titanium nitrade (TiNx), a platinum (Pt), a tantalum (Ta), a tantalum nitride (TaNx), a neodymium (Nd), a scandium (Sc), a strontium a ruthenium oxide (SrRuxOy), a zinc oxide (ZnOx), an indium tin oxide (“ITO”), a tin oxide (SnOx), an indium oxide (InOx), a gallium oxide (GaOx), an indium zinc oxide (“IZO”), etc. The gate electrode 16 may have a single-layered or multi-layered structure including the metal, the metal nitride, the conductive metal oxide and/or the transparent conductive material.

In an exemplary embodiment, a gate line (not illustrated) electrically connected to the gate electrode 16 is disposed on the gate insulation layer 15. The gate signal may be applied to the gate electrode 16 through the gate line. The gate line may include a substantially the same or similar material as the material in the gate electrode 16. The gate line may have a single-layered or multi-layered structure including the metal, the metal nitride, the conductive oxide and/or the transparent conductive material.

The insulating interlayer 17 may be disposed on the gate insulation layer 15 covering the gate electrode 16. The insulating interlayer 17 may include at least one of an oxide, a nitride, an oxynitride, an organic insulating material, etc. In one exemplary embodiment, for example, the insulating interlayer 17 may include a silicon oxide, a silicon nitride, a silicon oxynitride, an acryl-based resin, a polyimide-based resin, a siloxane-based resin or a combination thereof. The insulating interlayer 17 disposed on the gate insulation layer 15 may have a substantially uniform thickness along the profile of the gate electrode 16. In another exemplary embodiment, the insulating interlayer 17 may substantially covers the gate electrode 16 and have a substantially flat surface.

The source electrode 18 and the drain electrode 19 may be electrically connected to the second impurity area 14 and the first impurity area 12, respectively, through the insulating interlayer 17 and the gate insulation layer 15. The source electrode 18 and the drain electrode 19 may include at least one of a metal, a metal nitride, a conductive metal oxide, a transparent conductive material, etc. In one exemplary embodiment, for example, the source electrode 18 and the drain electrode 19 may include an aluminum, an aluminum alloy, an aluminum nitride, a silver, a silver alloy, a tungsten, a tungsten nitride, a copper, a copper alloy, a nickel, a chrome, a molybdenum, a molybdenum alloy, a titanium, a titanium nitrade, a platinum, a tantalum, a tantalum nitride, a neodymium, a scandium, a strontium ruthenium oxide, a zinc oxide, an ITO, a tin oxide, an indium oxide, a gallium oxide, an IZO or a combination thereof. The source electrode 18 and the drain electrode 19 may have a single-layered or multi-layered structure including the metal, the metal nitride, the conductive metal oxide, and/or the transparent conductive material.

In an exemplary embodiment, a data line (not illustrated) electrically connected to the source electrode 18 may be disposed on the insulating interlayer 17, and a data signal may be applied to the source electrode 18 through the data line. The data line may include a substantially same or similar material as the material included in the source electrode 18. The data line may have a single-layered structure or multi-layered structure including the metal, the metal nitride, the conductive metal oxide and/or the transparent conductive material. The gate line and the data line may cross each other. In one exemplary embodiment, the gate line and the data line may extend along substantially perpendicular directions, respectively, on the base substrate 10.

The insulation layer 30 may be disposed on the insulating interlayer 17, and the insulation layer 30 may cover the source electrode 18 and the drain electrode 19 of the thin film transistor 20. A contact hole that exposes a portion of the drain electrode 19 may be defined in the insulation layer 30. The insulation layer 30 may include a transparent insulating material such as a transparent plastic, a transparent resin, etc. In one exemplary embodiment, for example, the insulation layer 30 may include a benzo-cyclo-butene-based resin, an olefin-based resin, a polyimide-based resin, an acrylic-based resin, a polyvinyl-based resin, a siloxan-based resin, or a combination thereof. In an exemplary embodiment, the insulation layer 30 may have a substantially flat surface provided by a planarization process. In one exemplary embodiment, for example, the insulation layer 30 may be planarized by a chemical mechanical polishing (“CMP”) or an etch-back. In another exemplary embodiment, the insulation layer 30 may include a material having a self planarizing property.

FIG. 2 is a cross-sectional view illustrating an exemplary embodiment of a light emitting element of the organic light emitting display device of FIG. 1.

Referring to FIGS. 1 and 2, the light emitting element 130 includes a first electrode 110, a hole injection layer 112, a hole transport layer 114, a light emitting layer 117, an electron transport layer 118, an electron injection layer 119 and a second electrode 120.

The first electrode 110 may be disposed on the insulation layer 30. In an exemplary embodiment, the first electrode 110 may extend through the contact hole defined in the insulation layer 30, and the first electrode 110 may be connected to the thin film transistor 20. In one exemplary embodiment, for example, the first electrode 110 may be electrically connected to a portion of the drain electrode 19 exposed by the contact hole defined in the insulation layer 30. In another exemplary embodiment, a contact (not illustrated), a plug (not illustrated) or a pad (not illustrated), for example, may be additionally disposed in the contact hole defined in the insulation layer 30. In such an embodiment, the first electrode 110 may be electrically connected to the drain electrode 19 by the contact, the plug or the pad.

In an exemplary embodiment, where the organic light emitting display device is top emission type, the first electrode 110 may be a reflective electrode having a reflectivity. In such an embodiment, the second electrode 120 may be a transmitting electrode, which is transmissive, or a transflective electrode, which is semi-translucent. In another exemplary embodiment, where the organic light emitting display device is bottom emission type, the first electrode 110 may be a transmitting electrode or a transflective electrode, and the second electrode 120 may be a reflective electrode. Herein, “the reflectivity” means that a reflectance by an incident light is in a range of about 70% to about 100%. “The semi translucent” and “transflective” mean that a reflectance by an incident light is in a range of about 30% to about 70%. “The transmissive” means that a reflectance by an incident light is equal to or less than about 30%.

In an exemplary embodiment, where the first electrode 110 is a reflective electrode, the first electrode 110 may include at least one of a metal or a metal alloy relatively having a high reflectance. In one exemplary embodiment, for example, the first electrode 110 may include an aluminum, a silver, a platinum, a gold (Au), a chrome, a tungsten, a molybdenum, a titanium, a palladium (Pd), an alloy thereof or a combination thereof. In one exemplary embodiment, for example, the alloy in the first electrode 110 may be a silver-copper-gold (Ag—Cu—Au: “ACA”), a silver-protactinium-copper (Ag—Pa—Cu: “APC”), etc. According to an exemplary embodiment, the first electrode 110 may have a single-layered or multi-layered structure including the metal and/or the alloy.

In an exemplary embodiment, where the second electrode 120 is a transflective electrode, the second electrode 120 may include a thin metal layer. In such an embodiment, the second electrode 120 may have both a reflectance and a transmittance. When the second electrode 120 is substantially thick, e.g., thicker than a predetermined thickness, the luminous efficiency of the organic light emitting display device may be decreased. In an exemplary embodiment, the second electrode 120 may be substantially thin, e.g., thinner than the predetermined thickness. In one exemplary embodiment, for example, the second electrode 120 may have a thickness substantially equal to or less than about 30 nanometers (nm). In one exemplary embodiment, for example, and the second electrode 120 may have a thickness substantially equal to or less than about 20 nm. In an exemplary embodiment, the second electrode 120 may include at least one of an aluminum, a silver, a platinum, a gold, a chrome, a tungsten, a molybdenum, a titanium, a palladium, an alloy thereof and a combination thereof. In another exemplary embodiment, the second electrode 120 may include a transparent conductive material. In one exemplary embodiment, for example, the second electrode 120 may include at least one of an IZO, an ITO, a gallium tin oxide, a zinc oxide (ZnOx), a gallium oxide, a tin oxide, an indium oxide and a combination thereof. In another exemplary embodiment, the second electrode 120 may have a multi-layered structure including a plural of transmitting layers having different refractive index, or a plurality of transflective layers.

In an exemplary embodiment, the first electrode 110 may be an anode that provides holes to the hole injection layer 112 of the organic light emitting element 130, and the second electrode 120 may be a cathode that provides electrons to the electron injection layer of the organic light emitting element. In another exemplary embodiment, the first electrode 110 may function as the cathode, and the second electrode 120 may function as the anode. In such an embodiment, a stacking sequence of the hole injection layer 112, the light emitting layer 117, and the electron injection layer 119, for example, may be determined based on functions of the first electrode 110 and the second electrode 120.

In an exemplary embodiment, as shown in FIG. 1, the pixel definition layer 40 may be disposed on the first electrode 110 to cover the first electrode 110. In such an embodiment, a pixel or a pixel area of the organic light emitting display device may be defined by the pixel definition layer 40.

Referring to FIG. 2, in an exemplary embodiment, the hole injection layer 112 may be disposed on the first electrode 110. In such an embodiment, the first electrode 110 is an anode. In another exemplary embodiment, the hole injection layer 112 may be disposed under side of the second electrode 120. In such an embodiment the second electrode 120 is an anode. In one exemplary embodiment, for example, the hole injection layer 112 may include at least one of a 4,4′,4″-tris(3-methylphenylamino)triphenylamine (“m-MTDATA”), a 3,5-tris[4-(3-methylphenyl amino)phenyl]benzene (“m-MTDAPB”), a phthalocyanine compound such as copper phthalocyanine (“CuPc”), a 4,4′,4″-tris(N-carbazolyl)triphenylamine (“TCTA”), which is one of starburst type amines, and a N,N′-di(4-(N,N′-diphenylamino)phenyl)-N,N′-diphenylbenzidine (“DNTPD”). However, the material in the hole injection layer 112 should not be limited by the materials listed above. In such an embodiment, the hole injection layer 112 substantially improves electrical property of the light emitting element 130 for an efficient movement of the holes provided from the first electrode.

In an exemplary embodiment, the hole transport layer 114 may be disposed on the hole injection layer 112. In one exemplary embodiment, for example, the hole transport layer 114 may include a N-phenylcarbazole, a polyvinylcarbazole, a 1,3,5-tricarbazole-benzene, 4,4′-bis carbazolyl biphenyl, a m-bis carbazolyl phenyl, 4,4′-bis carbazolyl-2,2′-dimethyl biphenyl, a 4,4′,4″-tri(N-carbazolyl)triphenylamine, a 1,3,5-tri(2-carbazolyl phenyl)benzene, a 1,3,5-tris(2-carbazolyl-5-methoxy phenyl)benzene, a bis(4-carbazolyl phenyl)silane, a N,N′-diphenyl-N,N′-bis(1-naphthyl)-(1,1′-biphenyl)-4,4′-diamine (“NPB”), a N,N′-di(naphthalene-1-yl)-N,N′-diphenyl benezidine (“α-NPD”), a N,N-bis(3-methylphenyl)-N,N-diphenyl-(1,1-biphenyl)-4,4-diamine (“TPD”), a poly(9,9-dioctylfluorene-co-N-(4-butylphenyl)diphenylamine (“TFB”), a poly(9,9-dioctylfluorene-co-bis-(4-butylphenyl-bis-N,N-phenyl-1,4-phenylenediamin) (“PFB”), or a combination thereof. In such an embodiment, the hole transport layer 114 substantially improves transport property of holes provided from the hole injection layer 112.

In an exemplary embodiment, the light emitting layer 117 may be disposed on the hole transport layer 114. The light emitting layer 117 may include a light emission host and a light emission dopant. The light emitting element of the organic light emitting display device may be divided into a fluorescence type and a phosphorescence type according to emission principle. When the excitons formed by electrons and holes provided from the first electrode 110 and the second electrode 120 are transferred from a excited stated to a ground state, the phosphorescence is a phenomenon of light emission by some energy created when the excitons are transferred from a triplet state to the ground state, and the fluorescence is a phenomenon of light emission by some energy created when the excitons are transferred from a singlet state to the ground state. “The light emission” is a concept encompassing “fluorescence” and “phosphorescence”. Thus, herein, “the light emitting layer”, “the light emitting element”, “the light emission host”, “the light emission dopant”, etc., should be understood as an element encompassing “fluorescence type” and/or “phosphorescence type”. The light emission host may include a tris(8-hydroxyquinolinato)aluminum (“Alq3”), a 9,10-di(naphth-2-yl)anthracene (“ADN”), a 3-tert-butyl-9,10-di(naphth-2-yl)anthracene (“TBADN”), a 4,4′-bis(2,2-diphenyl-ethene-1-yl)-4,4′-dimethylphenyl (“p-DMDPNBi”), a tert(9,9-diarylfluorene)s (“TDAF”), a 2-(9,9′-spirobifluorene-2-yl)-9,9′-spirobifluorene (“BSDF”), a 2,7-bis(9,9′-spirobifluorene-2-yl)-9,9′-spirobifluorene (“TSDF”), a bis(9,9-diarylfluorene)s (“BDAF”), a 4,4′-bis(2,2-diphenyl-ethene-1-yl)-4,4′-di-(tert-buthyl)phenyl (“p-TDPVBi”), or a combination thereof, as a fluorescence type host. The light emission host may also include a 1,3-bis(carbazol-9-yl)triphenylamine (“TcTa”), a 4,4′-bis(carbazol-9-yl)biphenyl (“CBP”), a 4,4′-bis(9-carbazolyl)-2,2′-dimethyl-biphenyl (“CDBP”), a 4,4′-bis(carbazol-9-yl)-9,9-dimethyl-fluorene (“DMFL-CBP”), a 4,4′-bis(carbazol-9-yl)-9,9-bis(9-phenyl-9H-carbazol)fluorine (“FL-4CBP”), a 4,4′-bis(carbazol-9-yl)-9,9-di-tolyl-fluorene (“DPFL-CBP”), a 9,9-bis(9-phenyl-9H-carbazol)fluorine (“FL-2CBP”), or combination thereof, as a phosphorescence type host. However, the light emission host should not be limited by the materials listed above.

The light emission dopant of the light emitting element 130 emits light having specific wavelength by transition energy provided from the light emission host in the light emitting layer 117. In an exemplary embodiment, the light emitting element 130 may include various dopant materials. In one exemplary embodiment, for example, the light emission dopant may be a red light emission dopant, and the red light emission dopant may include a Octaethylporphine (“PtOEP”), a tris[1-phenylisoquinoline-C2, N]iridium(III) (“Ir(piq)3”), a acetylacetonate (Btp2Ir(acac)), a 4-(Dicyanomethylene)-2-tert-butyl-6-(1,1,7,7,-tetramethyljulolidyl-9-enyl)-4H-pyran (“DCJTB”), or a combination thereof. In one exemplary embodiment, for example, the light emission dopant may be a green light emission dopant, and the green light emission dopant may include a tris[2-phenylpyidineato-C2, N]iridium(III) (“Ir(ppy)3”), a Bis(2-phenylpyridine) (acetylacetonate) iridium(III) (“Ir(ppy)2(acac)”), a tris[2-(p-tolyl)pyridine]iridium(III) (“ir(mppy)3”), or a combination thereof. In one exemplary embodiment, for example, the light emission dopant may be a blue light emission dopant, and the blue light emission dopant may include a bis[4,6-difluorophenyl-pyridinato-N,C2] (“F2Irpic”), a bis(4′,6′-difluorophenylpyridinato)(3-(trif(“Ir(dfppz)3”), a ter-fluorene, or a combination thereof.

In general, more electrons flow into the light emitting layer than holes in the light emitting element, because the energy barrier between the hole transport layer and light emitting layer is higher than the energy barrier between the electron transport layer and light emitting layer. In the light emitting element, the electrons meet the holes at a boundary of the hole transport layer and light emitting layer because the mobility of electrons is faster than the mobility of holes. As a result, the excitons formed by electrons and holes are accumulated at the boundary of the hole transport layer and light emitting layer, such that non-light emission quenching may occur. In a light emitting element, the hole injection property may be substantially improved by applying much higher voltage to the first electrode 110 and the second electrode 120 to effectively prevent or substantially reduce the non-light emission quenching. In such a light emitting element, the driving voltage may be increased, and lifetime of the organic light emitting display device may be thereby shortened. In a light emitting element, the quenching substantially occurs in a green light emitting layer.

Therefore, according to an exemplary embodiment, the light emitting layer 117 of the light emitting element 130 has a light emission host and a light emission dopant by a proper weight ratio, and the light emitting layer 117 has a proper thickness to minimize non-light emission quenching. In an exemplary embodiment, a doping ratio of the light emission dopant may be a weight ratio of about 10% to about 15% with reference to an overall material weight, e.g., when the overall material weight of the light emitting element 130 is 100%. In one exemplary embodiment, for example, the light emitting layer 117 may include the light emission host and the light emission dopant by a weight ratio of about 85:10 to about 90:10. When the doping ratio of light emission dopant is greater than about 15%, a substantial amount of excitons are formed, and the excitons may be accumulated at the boundary of the hole transport layer 114 and the light emitting layer 117, such that non-light emission quenching may be increased. When the doping ratio of the light emission dopant is less than about 10%, the luminous efficiency of the organic light emitting display device may be decreased.

In an exemplary embodiment, the light emitting layer 117 has a thickness in a predetermined range. When the thickness of the light emitting layer 117 is substantially slim (e.g., less than the thickness in the predetermined range), a leakage current may be generated, and a light emission area may be decreased. When the thickness of the light emitting layer 117 is substantially thick (e.g., greater than the thickness in the predetermined range), the driving voltage of organic light emitting display device will be increased. In one exemplary embodiment, for example, the light emitting layer 117 may have a thickness in a range of about 10 nm to about 500 nm. In an alternative exemplary embodiment, the light emitting layer 117 have a thickness in a range of about 30 nm to about 50 nm. In such an embodiment, where the light emitting layer 117 has a thickness of about 30 nm to about 50 nm, sufficient luminous efficiency may be realized, and the non-light emission quenching is substantially effectively decreased.

In an exemplary embodiment, the electron transport layer 118 may be disposed on the light emitting layer 117. The electron transport layer 118 efficiently transfers the electrons provided from the electron injection layer 119, and the electron transport layer 118 may include a phenanthroline derivative, an anthracene derivative, a pyrimidine derivative, a pyridine derivative, a metal complex of a benzoquinoline derivative, or a combination thereof. In one exemplary embodiment, for example, the electron transport layer 118 may include a 2,9-dimethyl-4,7-diphenylphenanthroline (“DPhPhen”), a poly[(9,9-di-hexylfluorene-2,7-diyl)-co-(pyridine-3,5-diyl)] (“PF-Py”), a bis(10-hydroxybenzo[h]quinolinato)beryllium (“Bebq2”), or a combination thereof.

In an exemplary embodiment, the electron injection layer 119 may be disposed on the electron transport layer 118. The electron injection layer 119 effectively injects the electrons from the cathode. In an exemplary embodiment, the electron injection layer 119 may be omitted. In one exemplary embodiment, for example, the electron injection layer 119 may include a lithium fluoride (LiF), a sodium chloride (NaCl), a barium fluoride (BaF), a caesium fluoride (CsF), a lithium oxide (Li₂O), an aluminum oxide (Al₂O₃), a barium oxide (BaO), a fullerene (C₆₀), or a combination thereof.

Referring back to FIG. 1, the protective layer 200 encapsulates the light emitting element 130 and the thin film transistor 20, and protects the light emitting element 130 and the thin film transistor 20 from an external environment. The protective layer 200 may have a chemical stability to protect the light emitting element from the external gas or moisture, and the protective layer may have sufficient transparency of visible light to effectively display image. In such an embodiment, a surface of the protective layer 200 may include a glass, a transparent film, an organic insulation layer or an inorganic insulation layer.

According to exemplary embodiments, the light emitting element 130 includes the light emission host and the light emission dopant by a predetermined weight ratio, and the light emitting layer 117 has a predetermined thickness, such that the accumulation of the excitons at the boundary of the hole transport layer 114 and the light emitting layer 117 is substantially decreased. In such embodiments, luminous efficiency of the organic light emitting display device is substantially improved without applying a high voltage to the first and second electrodes 110 and 120.

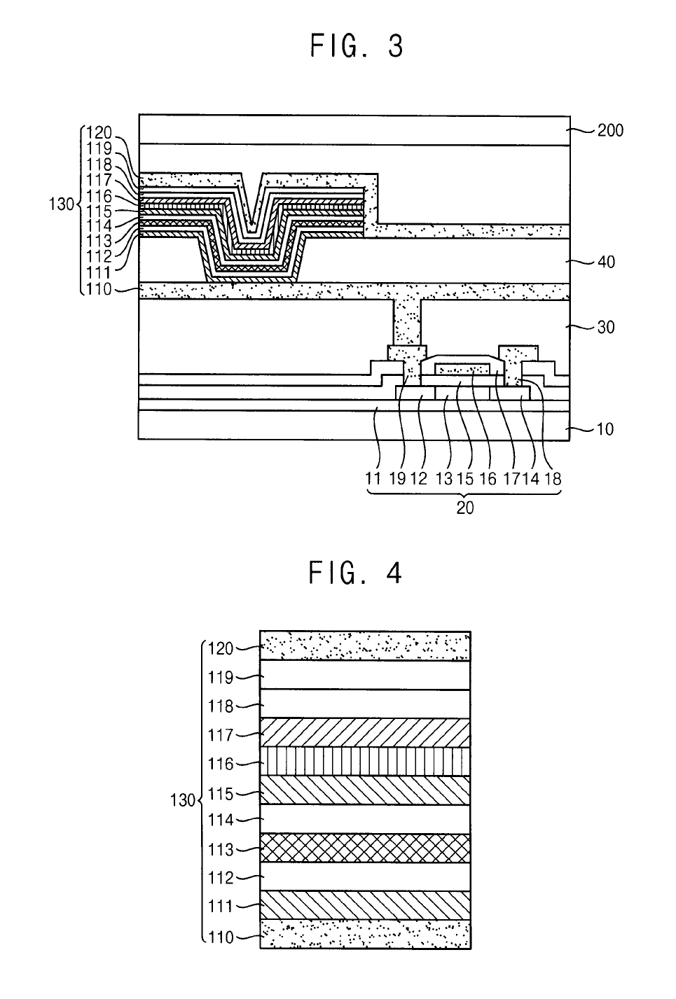

FIG. 3 is a cross-sectional view illustrating an alternative exemplary embodiment of an organic light emitting display device in accordance with the invention, and FIG. 4 is a cross-sectional view illustrating an exemplary embodiment of a light emitting element of the organic light emitting display device of FIG. 3.

Referring to FIG. 3, an alternative exemplary embodiment of the organic light emitting display device includes a base substrate 10, a thin film transistor 20, an insulation layer 30, a pixel definition layer 40, a light emitting element 130 and a protective layer 200. The organic light emitting display device in FIGS. 3 and 4 is substantially the same as the organic light emitting display device shown in FIGS. 1 and 2 except for the light emitting element 130. The same or like elements shown in FIGS. 3 and 4 have been labeled with the same reference characters as used above to describe the exemplary embodiments of the organic light emitting display device shown in FIGS. 1 and 2, and any repetitive detailed description thereof may hereinafter be omitted or simplified.

Referring to FIG. 4, the light emitting element 130 includes a first electrode 110, a hole injection layer 112, a hole transport layer 114, a light emitting layer 117, an electron transport layer 118, an electron injection layer 119 and a second electrode 120. In such an embodiment, the light emitting element 130 may further include a host layer 116 including a light emission host, and the host layer 116 is disposed between the light emitting layer 117 and the hole transport layer 114. In another exemplary embodiment, the light emitting element 130 may further include a first intermediate layer 111 disposed on the first electrode 110. In another exemplary embodiment, the light emitting element 130 may further include a second intermediate layer 113 disposed on the hole injection layer 112. In still another exemplary embodiment, the light emitting element 130 may further include a third intermediate layer 115 disposed on the hole transport layer 114.

In an exemplary embodiment, each of the first electrode 110 and the second electrode 120 may be an anode or a cathode. In an exemplary embodiment, where the organic light emitting display device is top-emission type, the first electrode 110 may be a reflective electrode and the second electrode 120 may be a transmitting electrode or a transflective electrode. In an exemplary embodiment, where the organic light emitting display device is bottom-emission type, the first electrode 110 may be a transmitting electrode or a transflective electrode, and the second electrode 120 may be a reflective electrode. The first electrode 110 and the second electrode 120 are be substantially the same as the first electrode 110 and the second electrode 120 of the exemplary embodiment of the light emitting element 130 illustrated in FIG. 2, and any repetitive detailed description thereof will be omitted.

In an exemplary embodiment, where the first electrode 110 is an anode, the hole injection layer 112 may be disposed on the first electrode 110. In an exemplary embodiment, where the first electrode 110 is a cathode, the hole injection layer 112 may be disposed on an underside (e.g., a lower surface) of the second electrode 120. The hole injection layer 112 is substantially the same as the hole injection layer 112 of the exemplary embodiment of the light emitting element 130 shown in FIG. 2, and any repetitive detailed description thereof will be omitted.

The hole transport layer 114 is disposed on the second intermediate layer 113. The hole transport layer 114 may include a hole transport material, and the hole transport layer 114 is substantially the same as the hole transport layer 114 of the exemplary embodiment of the light emitting element 130 of FIG. 2, and any repetitive detailed description thereof will be omitted.

The light emitting layer 117 is disposed on the host layer 116. In an exemplary embodiment, the light emitting layer 117 may include a light emission host and a light emission dopant. In an exemplary embodiment, the light emission host may be a fluorescence type host, and the fluorescence type host may include an Alq3, an ADN, a TBADN, a 4p-DMDPNBi, a TDAF, a BSDF, a TSDF, a BDAF, p-TDPVBi, or a combination thereof. In an exemplary embodiment, the light emission host may be a phosphorescence type host, and the phosphorescence type host may include a TcTa, a CBP, a CDBP, a DMFL-CBP, a FL-4CBP, a DPFL-CBP, a FL-2CBP, or a combination thereof. However, the light emission host should not be limited by the materials listed above.

The light emission dopant emits a light having specific wavelength by transition energy provided from the light emission host, in the light emitting layer 117. Thus, a various light emitting elements might be provided according to selecting a proper dopant material. In one exemplary embodiment, for example, the light emission dopant may be a red light emission dopant, the red light emission dopant may include a PtOEP, an Ir(piq)3, a Btp2Ir(acac), a DCJTB, or a combination thereof. In one exemplary embodiment, for example, the light emission dopant may be a green light emission dopant, and the green light emission dopant may include an Ir(ppy)3, an Ir(ppy)2(acac), an ir(mppy)3, or a combination thereof. In one exemplary embodiment, for example, the light emission dopant may be a blue light emission dopant, and the blue light emission dopant may also include a F2Irpic, a Bis(4′,6′-difluorophenylpyridinato)(3-(trif(Ir(dfppy)2(fptz), a ter-fluorene, or a combination thereof.

In an exemplary embodiment, as shown in FIG. 4, the electron transport layer 118 may be disposed on the light emitting layer 117, and the electron injection layer 119 may be disposed on the electron transport layer 118. The electron transport layer 118 and the electron injection layer 119 are substantially the same as the electron transport layer 118 and the electron injection layer 119 of the exemplary embodiment of the light emitting element 130 of FIG. 2, and any repetitive detailed description thereof will be omitted.

In an exemplary embodiment, as shown in FIG. 4, the host layer 116 may be disposed between the hole transport layer 114 and the light emitting layer 117, and may include a light emission host. In such an embodiment, the host layer 116 is disposed substantially close to the light emitting layer 117, and the host layer 116 does not include the light emission dopant, such that the host layer 116 may minimize an accumulation of the excitons at the boundary of the hole transport layer 114, and the quenching by the holes and the excitons is thereby effectively minimized. The light emission host of the host layer 116 is substantially same as the light emission host of the exemplary embodiment the light emitting layer 117 of the light emitting element 130, and any repetitive detailed description thereof will be omitted.

In an exemplary embodiment, the host layer 116 may have a thickness in a predetermined range. In one exemplary embodiment, for example, the host layer 116 may have a thickness in a range of about 0.1 nm to about 10 nm, but not being limited thereto. When the host layer 116 have a thickness greater than the thickness in the predetermined range (e.g., about 10 nm), the transition energy of the light emission host in the host layer 116 may not be effectively transferred to the light emission dopant of the light emitting layer 117. When the host layer 116 have a thickness less than about 0.1 nm, the quenching may not be decreased.

In an exemplary embodiment, where the first electrode 110 is an anode, the first intermediate layer 111 may be disposed on the first electrode 110. In an exemplary embodiment, where the first electrode 110 is a cathode, the first intermediate layer 111 may be disposed on an underside (e.g., a lower surface) of the second electrode 120. In an exemplary embodiment, the first intermediate layer 111 may include a pyrazine compound, and the pyrazine compound may have the following chemical structure.

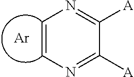

In the chemical structure above, the “Ar” in the chemical structure may be an aryl group, and the “A” may be a hydrogen (H), an alkyl group, an alkoxy group, a dialkylamine group, having the carbons of C₁ to C₁₀, or a fluorine (F), a chlorine (Cl), a bromine (Br), an iodine (I), or a nitrile group (—CN). In an alternative exemplary embodiment, the pyrazine compound may include a hexaazatriphenylene compound having the following chemical structure.

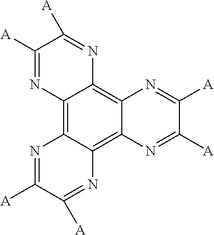

In the chemical structure above, the “A” may be a hydrogen, an alkyl group, an alkoxy group, a dialkylamine group, having the carbons of C₁ to C₁₀, or a fluorine, a chlorine, a bromine, an iodine, or a nitrile group. In one exemplary embodiment, for example, all “A” in the hexaazatriphenylene compound may be nitrile groups. In such an embodiment, the hexaazatriphenylene compound is a hexaazatriphenylene-hexacarbonitrile (“HAT-CN6”).

In an exemplary embodiment, an absolute value of the differential of a lowest unoccupied molecular orbital (“LUMO”) energy level of the first intermediate layer 111 and a highest occupied molecular orbital (“HOMO”) energy level of the hole injection layer 112 is substantially small such that the first intermediate layer 111 may efficiently draw electrons from the hole injection layer 112. In such an embodiment, an absolute value of the differential of the LUMO energy level of the first intermediate layer 111 and the work function level of the cathode is substantially great such that the holes are efficiently injected by bondage of the drawn electrons at the first intermediate layer 111. As a result, in such an embodiment, the first intermediate layer 111 may improve the hole injection property with low driving voltage. In one exemplary embodiment, for example, the first intermediate layer 111 may have a thickness in a range of about 0.1 nm to about 10 nm, but not being limited thereto.

In an exemplary embodiment, as shown in FIG. 4, the second intermediate layer 113 may be disposed on the hole injection layer 112, and may have a hole injection material and hole transport material. In one exemplary embodiment, for example, the hole injection material may include a m-MTDATA, m-MTDATPB, a phthalocyanine compound such as copper phthalocyanine, a TCTA as one of the starburst type amines, DNTPD or a combination thereof. However, the material in the hole injection material is not limited to the materials listed above. The hole transport material may include a n-phenylcarbazole, a polyvinylcarbazole, a 1,3,5-tricarbazole-benzene, a 4,4′-bis carbazolyl biphenyl, a m-bis carbazolyl phenyl, 4,4′-bis carbazolyl-2,2′-dimethyl biphenyl, a 4,4′,4″-tri(N-carbazolyl)triphenylamine, a 1,3,5-tri(2-carbazolyl phenyl)benzene, a 1,3,5-tris(2-carbazolyl-5-methoxy phenyl)benzene, a bis(4-carbazolyl phenyl)silane, a NPB, a α-NPD, a TPD, a TFB, a PFB, or a combination thereof, but not being limited thereto. The second intermediate layer 113 may improve hole injection property as the second intermediate layer 113 includes the hole injection material and the hole transport material. In an exemplary embodiment, the second intermediate layer 113 allows the holes to be efficiently transferred to the hole transport layer 114. The second intermediate layer 113 may have the hole injection material and the hole transport material by a weight ratio of about 1:99 to about 99:1, and may have a thickness in a range of about 0.1 nm to about 10 nm, but not being limited thereto.

In an exemplary embodiment, as shown in FIG. 4, the third intermediate layer 115 is disposed on the hole transport layer 114, and has a pyrazine compound. In one exemplary embodiment, for example, the pyrazine compound may be a hexaazatriphenylene compound. In such an embodiment, an absolute value of the differential of a LUMO energy level of the third intermediate layer 115 and a HOMO energy level of the host layer 116 is substantially small such that the third intermediate layer 115 may efficiently draw electrons from the host layer 116. In such an embodiment, an absolute value of the differential of the LUMO energy level of the third intermediate layer 115 and a LUMO energy level of the hole transport layer 114 is substantially great such that the holes are injected easily by bondage of the drawn electrons at the third intermediate layer 115. As a result, in such an embodiment, the third intermediate layer 115 may substantially improve the hole injection property with low driving voltage. In such an embodiment, the pyrazine compound and the hexaazatriphenylene compound are substantially the same as the pyrazine compound and the hexaazatriphenylene compound in the first intermediate layer 111, and any repetitive detailed description thereof will be omitted. The third intermediate layer 111 may have a thickness in a range of about 0.1 nm to about 10 nm to inject the holes substantially efficiently to the host layer 116 and the light emitting layer 117. However, the third intermediate layer 115 is not limited to the exemplary embodiments set forth herein.

In an exemplary embodiment, the light emitting element 130 includes the first intermediate layer 111, the second intermediate layer 113 and the third intermediate layer 115 such that driving voltage for injection of the holes in the light emitting element 130 may be substantially reduced. In an exemplary embodiment, the host layer 116 not having the light emission dopant is disposed on the boundary of the light emitting layer 117 and the hole transport layer 114 such that the non-light emission quenching is decreased by minimizing the accumulating the excitons at the boundary of the light emitting layer 117 and the hole transport layer 114. Therefore, in such an embodiment, the driving voltage of the organic light emitting display device including the light emitting element 130 is substantially decreased, and the luminous efficiency is substantially improved.

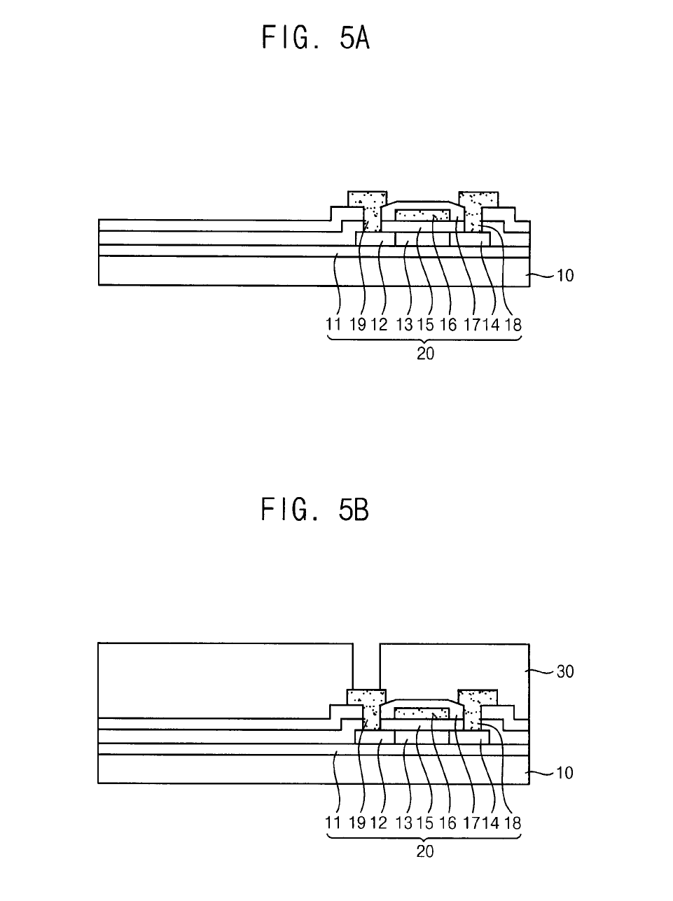

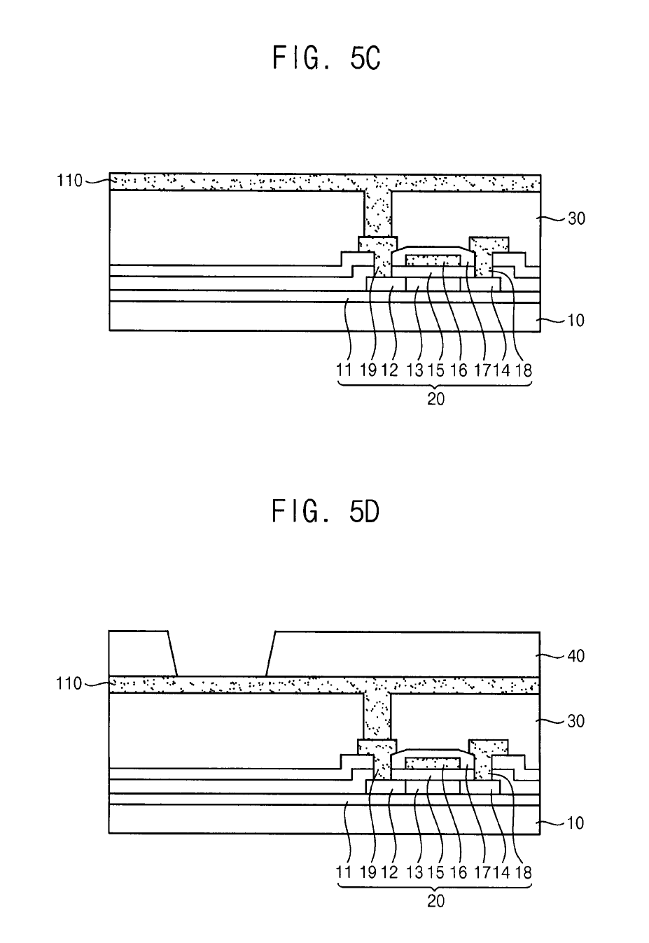

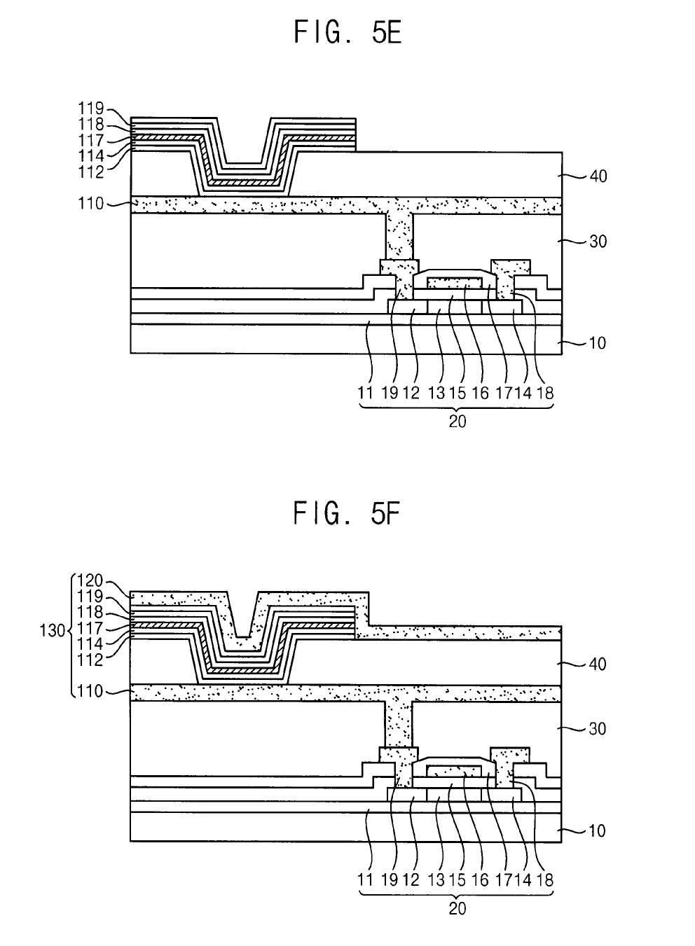

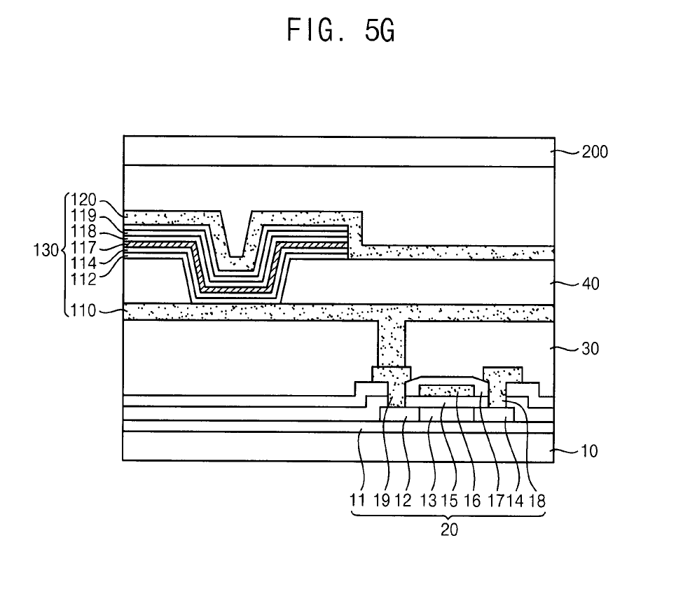

FIGS. 5A to 5G are cross sectional views illustrating an exemplary embodiment of a method of manufacturing the organic light emitting display device in accordance with the invention. Hereinafter, referring to the FIGS. 5A to 5G, an exemplary embodiment of a method of manufacturing an organic light emitting display device, e.g., the exemplary embodiment of the organic light emitting display device of FIGS. 1 and 2, will be described, but not being limited thereto. In an alternative exemplary embodiment, another organic light emitting display device, e.g., the exemplary embodiment of the organic light emitting display device of FIGS. 3 and 4, may be manufactured based on such an embodiment of the method, e.g., by omitting or adding well known processes therefrom or thereto.

Referring to FIG. 5A, in an exemplary embodiment of the method, a thin film transistor 20 may be provided, e.g., formed, on a base substrate 10. In such an embodiment, the thin film transistor 20 may include a buffer layer 11, a semiconductor layer 12, 13 and 14, a gate insulation layer 15, a gate electrode 16, an insulating interlayer 17, a source electrode 18 and a drain electrode 19.

In such an embodiment, the buffer layer 11 may be provided on the base substrate 10 including a transparent insulating material, and the buffer layer 11 may include an oxide, a nitride, an oxynitride, an organic insulating material, or a combination thereof. In an exemplary embodiment, the buffer layer 11 may be formed on the base substrate 10 by a chemical vapor deposition (“CVD”), a plasma-enhanced CVD (“PECVD”), a high-density-plasma CVD (“HDP-CVD”), a spin coating method, a thermal oxidation method, or a printing method, for example.

The semiconductor layer 12, 13 and 14 may be provided on the buffer layer 11. In one exemplary embodiment, for example, the gate insulation layer 15 may be directly formed on the buffer layer 11. In such an embodiment, the semiconductor layer 12, 13 and 14 may be formed with a silicon, and may be formed by a CVD, a PECVD, a HDP-CVD, a spin coating method, or a printing method, for example.

The gate insulation layer 15 may be formed with an oxide or an organic insulating material, for example. In an exemplary embodiment, the gate insulation layer 15 may be substantially uniformly provided along the profile of the semiconductor layer 12, 13 and 14, on the buffer layer 11. The gate insulation layer 15 may be formed by a sputtering method, a CVD, an atomic layer deposition (“ALD”), a HDP-CVD, a spin coating method, or a printing method, for example.

The gate electrode 16 may be provided on a portion of the gate insulation layer 15 that overlaps the semiconductor layer 12, 13 and 14. The gate electrode 16 may be formed with a metal, a metal nitride, a conductive metal oxide, a transparent conductive material, or a combination thereof, for example. The gate electrode 16 may be provided by a sputtering method, a CVD, an ALD, a spin coating method, a vacuum deposition, a pulsed-laser-deposition (“PLD”), or a printing method, for example.

A first impurity area 12 and a second impurity area 14 may be provided by doping impurity to a corresponding portion of the semiconductor layer 12, 13 and 14 using the gate electrode 16 as a mask. In an exemplary embodiment, as shown in FIG. 5A, the first impurity area 12 and the second impurity area 14 may be formed on each side portions of the semiconductor layer 12, 13 and 14, and a central portion of the semiconductor layer 12, 13 and 14 is defined as a channel area 13. In one exemplary embodiment, for example, the first impurity area 12 and the second impurity area 14 may be provided by an ion implantation method. In an exemplary embodiment, a gate line (not illustrated) may be provided on a portion of the gate insulation layer 15 during a process for providing the gate electrode 16. The gate line may extend in a predetermined direction (e.g., a first direction) on the gate insulation layer 15, and may be connected to the gate electrode 16.

The insulating interlayer 17 may be provided on the gate insulation layer 15 to cover the gate electrode 16. The insulating interlayer 17 may be formed with an oxide, a nitride, an oxynitride, an organic insulating material, or a combination thereof, for example. The insulating interlayer 17 may be provided by a sputtering method, a CVD, a PECVD, an ALD, a spin coating method, a vacuum deposition, a PLD, or a printing method, for example. In an exemplary embodiment, the insulating interlayer 17 may be substantially uniformly provided along the profile of the gate electrode 16, and on the gate insulation layer 15. In another exemplary embodiment, the insulating interlayer 17 may be provided to have substantially flat surface and to substantially cover the gate electrode 16.

Contact holes that expose a portion of the first impurity area 12 and a portion of the second impurity area 14 may be formed by etching a portion of the gate insulation layer 15 and the insulating interlayer 17. The source electrode 18 and the drain electrode 19 may be provided on the insulating interlayer 17 in the contact holes. Each of the source electrode 18 and the drain electrode 19 may be formed with a metal, a metal nitride, a conductive metal oxide, a transparent conductive material, or a combination thereof, for example, and each of the source electrode 18 and the drain electrode 19 may be provided by a sputtering method, a CVD, a PECVD, an ALD, a spin coating method, a vacuum deposition, a PLD, or a printing method, for example. The drain and source electrode 19 and 18 are connected to the first impurity area 12 and the second impurity area 14, respectively. According to an exemplary embodiment, a data line (not illustrated) may be provided on a portion of the insulating interlayer 17 during a process of providing the source electrode 18 and the drain electrode 19. The data line may be extend in a predetermined direction (e.g., a second direction different from the first direction) on the insulating interlayer 17, and may be connected to the source electrode 18.

Referring to FIG. 5B, an insulation layer 30 that covers the thin film transistor 20 may be provided on the base substrate 10. The insulation layer 30 may be formed with a transparent material such as a transparent plastic, a transparent resin, or a combination thereof, for example. The insulation layer 30 may be provided by a spin coating method, a printing method, a vacuum deposition, etc. In an exemplary embodiment, the insulation layer 30 may be planarized by a CMP, or an etch-back, for example. In another exemplary embodiment, the insulation layer 30 may be formed with a material having a self planarizing property. As a result, the insulation layer 30 may have flat upper surface. In an exemplary embodiment, a contact hole that exposes a portion of the drain electrode 19 may be formed by etching a portion of the insulation layer 30. In one exemplary embodiment, for example, the contact hole may be formed through the insulation layer 30 by a photolithography.

Referring to FIG. 5C, after providing a first conductive layer (not illustrated) on the insulation layer 30, and inside the contact hole of the insulation layer 30, a first electrode 110 may be provided by patterning the first conductive layer. In such an embodiment, the first electrode 110 may be directly connected to the drain electrode 19. The first conductive layer may be provided on the insulation layer 30 by a sputtering method, a printing method, a spray method, a CVD, an ALD, a vacuum deposition, or a PLD, for example. In such an embodiment, the first electrode 110 may be formed with a metal, an alloy, a transparent conductive material, or a combination thereof, for example. The first electrode 110 may be a reflective electrode, a transmitting electrode or a transflective electrode, which may be determined based on the type of the organic light emitting display device to be manufactured. In another exemplary embodiment, after providing a contact, a plug, or a pad, for example, in the contact hole in the insulation layer 30, the first electrode 110 may be provided on the insulation layer 30. In such an embodiment, the first electrode 110 may be electrically connected to the drain electrode 19 through the contact, plug, or pad, for example.

Referring to FIG. 5D, a pixel definition layer 40 may be provided on the first electrode 110 to cover the first electrode 110. The pixel definition layer 40 may be provided to cover a portion of a surface of the first electrode 110, and non-covered portion of the surface of the first electrode 110 may define a pixel area in which the light emitting element is provided. The pixel definition layer 40 may be provided by a spin coating method, a printing method, or a vacuum deposition, for example. The pixel definition layer 40 may be formed with an insulating material such as a photoresist, a polyacryl-based resin, a polyimide-based resin and an acryl-based resin, a silicon compound, or a combination thereof, for example.

Referring to FIG. 5E, a hole injection layer 112, a hole transport layer 114, a light emitting layer 117, an electron transport layer 118 and an electron injection layer 119 may be provided on a portion of the first electrode, 110, which is surrounded and exposed by the pixel definition layer 40. In an exemplary embodiment, the layers listed above may be provided by a various method such as a deposition, a mask sputtering, a photoresist method, a printing method, or an inkjet method, for example. In such an embodiment, the deposition includes a sputtering, a CVD, a PLD, a vacuum deposition, or an ALD, for example. In one exemplary embodiment, for example, the layers listed above may be provided by the mask sputtering including arraying a mask for exposing a portion of the first electrode 110, and directly depositing a raw material on the first electrode 110 through an opening of the mask, by heating and sputtering.

The hole injection layer 112 may be provided on the first electrode 110 by a deposition, a mask sputtering, a photoresist method, a printing method, or an inkjet method, for example. The hole injection layer 112 may be formed with a TCTA, a m-m-MTDATA, a m-MTDAPB, or a combination thereof, for example.

The hole transport layer 114 may be provided on the hole injection layer 112 by a deposition, a mask sputtering, a photoresist method, a printing method, or an inkjet method, for example. The hole transport layer 114 may be formed with a TPD, an α-NPD, or a combination thereof, for example.

In an exemplary embodiment, the light emitting layer 117 may be provided on the hole transport layer 114. In such an embodiment, the light emitting layer 117 may be formed to have a thickness in a range of about 30 nm to about 50 nm, and may be formed with a light emission host and a light emission dopant by a weight ratio of about 85:15 to about 90:10. In an exemplary embodiment, a method of providing the light emitting layer 117 may include doping the light emission dopant to the light emitting layer 117 by diffusion or an ion implantation, after depositing or sputtering the light emission host. In another exemplary embodiment, the light emitting layer 117 may be provided by co-sputtering or co-depositing the light emission host and the light emission dopant. In still another exemplary embodiment, the light emitting layer 117 may be formed with a mixture of the light emission host and the light emission dopant by the weight ratio of about 85:15 to about 90:10, and the light emitting layer 117 may be formed by a deposition, a mask sputtering, a photoresist method, a printing method, or an inkjet method, for example, using the mixture. In such an embodiment, the light emission host may include an Alq3, an ADN, a TBADN, a 4p-DMDPNBi, a TDAF, a BSDF, a TSDF, a BDAF, p-TDPVBi, or a combination thereof, for example, as a fluorescence type host, or the light emission host may include a TcTa, a CBP, a CDBP, a DMFL-CBP, a FL-4CBP, a DPFL-CBP, a FL-2CBP, or a combination thereof, for example, as a phosphorescence type host. The light emission dopant may include a PtOEP, an Ir(piq)3, a Btp2Ir(acac), a DCJTB, or a combination thereof, for example, as a red light emission dopant, the light emission dopant may include an Ir(ppy)3, an Ir(ppy)2(acac), an Ir(mppy)3, or a combination thereof, for example, as a green light emission dopant, or the light emission dopant may include a F2Irpic, an Ir(dfppz)3, a ter-fluorene, or a combination thereof, for example, as a blue light emission dopant.

The electron transport layer 118 may be provided by a deposition, a mask sputtering, a photoresist method, a printing method, or an inkjet method, for example, on the light emitting layer 117. The electron transport layer 118 may be formed with a phenanthroline derivative, an anthracene derivative, a pyrimidine derivative, a pyridine derivative, a metal complex of a benzoquinoline derivative, or a combination thereof, for example.

The electron injection layer 119 may be provided on the electron transport layer 118 by a deposition, a mask sputtering, a photoresist method, a printing method, or an inkjet method, for example. In one exemplary embodiment, for example, the electron injection layer 119 may be formed with a LiF, a NaCl, a BaF, a CsF, a Li₂O, an Al₂O₃, a BaO, a C₆₀, or a combination thereof, for example.

Referring to FIG. 5F, a second conductive layer (not illustrated) may be provided to cover the electron injection layer 119 and the pixel definition layer 40 by a sputtering method, a printing method, a spray method, a CVD, an ALD, a vacuum deposition, or a PLD, for example, and the second electrode 120 may be provided by patterning the second conductive layer. The second electrode 120 may be formed with a metal, an alloy, a transparent conductive material, or a combination thereof, for example. In such an embodiment, the second electrode 120 may be a reflective electrode, a transmitting electrode or a transflective electrode, which may be determined based on the type of the organic light emitting display device to be manufactured.

Referring to FIG. 5G, the protective layer 200 may be provided on the second electrode 120 to encapsulate the thin film transistor 20 and the light emitting element 130. In one exemplary embodiment, for example, the protective layer 200 may be provided by bonding a protective substrate including a glass, a transparent metal film, an organic or inorganic insulator, for example, with the base substrate 10 using a sealing material. The bonding may be performed by hardening process using laser or ultraviolet, after spreading the sealing material at a portion of an inner or lower surface of the protective substrate. In an exemplary embodiment, the protective layer 200 may be provided to be spaced apart from the second electrode 120 by a predetermined gap or distance. In another exemplary embodiment, the protective layer 200 may be provided directly on the second electrode 120.

Hereinafter, an alternative exemplary embodiment of a method of manufacturing the organic light emitting display device will be described, referring back to FIG. 3.

Referring to FIG. 3, in an exemplary embodiment, the thin film transistor 20 may be provided on the base substrate 10, and an insulation layer 30 may be provided on the thin film transistor 20, and a first electrode 110 electrically connected to the drain electrode 19 of the thin film transistor 20 may be provided on the insulation layer 30. Methods of providing the thin film transistor 20, the insulation layer 30 and the first electrode 110 are substantially the same as the methods of providing the thin film transistor 20, the insulation layer 30 and the first electrode 110 described above with reference to FIGS. 5A to 5G, and any repetitive detailed description thereof will be omitted.

In an exemplary embodiment, the pixel definition layer 40 may be provided on the first electrode 110, and a first intermediate layer 111, a hole injection layer 112, a second intermediate layer 113, a hole transport layer 114, a third intermediate layer 115, a host layer 116, a light emitting layer 117, an electron transport layer 118 and an electron injection layer 119 may be provided on a portion of the first electrode 110, which is surrounded and exposed by the pixel definition layer 40.

The hole injection layer 112, the hole transport layer 114, the electron transport layer 118 and the electron injection layer 119 may be provided by substantially the same method as the exemplary embodiment of manufacturing the organic light emitting layer shown in FIGS. 5A to 5Q and any repetitive detailed description thereof will be omitted.

In an exemplary embodiment, the first intermediate layer 111 may be provided on the first electrode 110, and the third intermediate layer 115 may be provided on the hole transport layer 114. In one exemplary embodiment, for example, the first intermediate layer 111 and the third intermediate layer 115 may be formed with a pyrazine compound such as a HAT-CN6 which is one of the HAT compound, for example, and the first and third intermediate layer 111 and 115 may be provided by a various methods such as a deposition, a mask sputtering, a photoresist method, a printing method, or an inkjet method, for example.

In an exemplary embodiment, the second intermediate layer 113 may be provided on the hole injection layer 112. The second intermediate layer 113 may be formed with a hole injection material such as a CuPc, a TCTA, a m-MTDATA, and a m-MTDAPB, for example, and a hole transport material such as a TPD, and a α-NPD, for example. In such an embodiment, a weight ratio of the hole injection material and the hole transport material of the second intermediate layer 113 may be in a range of about 1:99 to about 99:1, and the second intermediate layer 113 may be provided by co-deposition or co-sputtering. In another exemplary embodiment, the second intermediate layer 113 may be provided by a deposition, a mask sputtering, a photoresist method, a printing method, or an inkjet method, for example, using a mixture of the hole injection material and the hole transport material by the weight ratio of about 1:99 to about 99:1.

In an exemplary embodiment, the host layer 116 may be provided on the third intermediate layer 115. In one exemplary embodiment, for example, the host layer 116 may include a fluorescence type host such as an Alq3, an ADN, and a TBADN, for example, or may include a phosphorescence type host such as TcTa, a CBP, a CDBP, a DMFL-CBP, a FL-4CBP, a DPFL-CBP and a FL-2CBP, for example. The host layer 116 may be provided by various methods such as a deposition, a mask sputtering, a photoresist method, a printing method, and an inkjet method, for example.

In an exemplary embodiment, the light emitting layer 117 may be provided on the host layer 116, by doping a light emission dopant by diffusion method or an ion implantation, for example, after depositing or sputtering the light emission host. In another exemplary embodiment, the light emitting layer 117 may be provided by co-depositing or co-sputtering the light emission host and dopant. In still another exemplary embodiment, the light emitting layer 117 may be provided by various methods such as a deposition, a mask sputtering, a photoresist method, a printing method, and an inkjet method, for example, using a mixture of the light emission host and dopant, which are mixed by a weight ratio of about 85:15 to about 90:10. In one exemplary embodiment, for example, the light emission host may include a fluorescence type host such as an Alq3, an ADN, a TBADN, etc., or may include a phosphorescence type host such as TcTa, a CBP, a CDBP, a DMFL-CBP, a FL-4CBP, a DPFL-CBP and a FL-2CBP, for example. The light emission dopant may include a PtOEP, an Ir(piq)3, a Btp2Ir(acac), a DCJTB, or a combination thereof, for example, as a red light emission dopant, and may include an Ir(ppy)3, an Ir(ppy)2(acac), an Ir(mpyp)3, or a combination thereof, for example, as a green light emission dopant, and may include a F2Irpic, an Ir(dfppz)3, a ter-fluorene, or a combination thereof, for example, as a blue light emission dopant.

Referring to FIG. 3, a second conductive layer (not illustrated) may be provided to cover the electron injection layer 119 and the pixel definition layer 40, and the second electrode 120 may be provided by patterning the second conductive layer. In such an embodiment, the method of providing the second electrode 120 is substantially the same as the method of providing the second electrode 120 described above with reference to FIGS. 5A to 5G and any repetitive detailed description thereof will be omitted.

Referring to FIG. 3, the protective layer 200 may be provided to encapsulate the thin film transistor 20 and the light emitting element 130. In such an embodiment, a method of providing the protective layer 200 is substantially the same as the method of providing the protective layer 200 described above with reference to FIGS. 5A to 5Q and any repetitive detailed description thereof will be omitted.

According to an exemplary embodiment of the method of manufacturing the organic light emitting display device, the organic light emitting display device, in which the non-light emission quenching is reduced and the hole injection property is improved, may be provided, and the lifetime and the luminous efficiency of the manufactured organic light emitting display device are improved.

Exemplary embodiments of the inventions relate to a display device including a light emitting element. Although the exemplary embodiments of the invention are mainly directed to a display device including a phosphorescence type of the light emitting element, the inventions may also apply to fluorescence type of the light emitting element. The inventions may apply to any light emitting element which those skilled in the art may obviously modify, based on the light emitting layer including the light emission host and dopant by a predetermined weight ratio and a predetermined thickness as disclosed herein. Exemplary embodiments of the organic light emitting display device including the light emitting element may be applied to a top emission type display device and a bottom emission type display device, and the exemplary embodiments the organic light emitting display device may be used as a monitor of television, desktop, laptop, personal digital assistant (“PDA”), cellular phone, global positioning system (“GPS”) navigator, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the exemplary embodiment of the invention. Accordingly, all such modifications are intended to be included within the scope of the invention as defined in the claims. Therefore, it is to be understood that the foregoing is illustrative of various exemplary embodiments and is not to be construed as limited to the specific exemplary embodiments disclosed herein, and that modifications to the disclosed exemplary embodiments, as well as other exemplary embodiments, are intended to be included within the scope of the appended claims.

What is claimed is:

1. A light emitting element comprising:
a first electrode;
a hole injection layer disposed on the first electrode;
a hole transport layer disposed on the hole injection layer;
a light emitting layer disposed on the hole transport layer, wherein the light emitting layer comprises a light emission host and a light emission dopant;
an electron transport layer disposed on the light emitting layer;
an electron injection layer disposed on the electron transport layer; and
a second electrode disposed on the electron injection layer.

2. The light emitting element of claim 1, wherein the light emission host and the light emission dopant of the light emitting layer are in a weight ratio of about 85:15 to about 90:10.

3. The light emitting element of claim 2, wherein the light emitting layer has a thickness in a range of about 30 nanometers to about 50 nanometers.

4. The light emitting element of claim 1, further comprising:
a host layer disposed between the hole transport layer and the light emitting layer, wherein the host layer comprises a light emission host.

5. The light emitting element of claim 4, further comprising:
a first intermediate layer disposed between the first electrode and the hole injection layer, wherein the first intermediate layer comprises a pyrazine compound.

6. The light emitting element of claim 5, wherein the pyrazine compound of the first intermediate layer comprises a hexaazatriphenylene compound.

7. The light emitting element of claim 6, further comprising:
a second intermediate layer disposed between the hole injection layer and the hole transport layer.

8. The light emitting element of claim 7, wherein the second intermediate layer comprises a hole injection material of the hole injection layer and a hole transport material of the hole transport layer.

9. The light emitting element of claim 8, further comprising:
a third intermediate layer disposed between the hole transport layer and the host layer, wherein the third intermediate layer comprises the pyrazine compound.

10. The light emitting element of claim 9, wherein the pyrazine compound of the third intermediate layer comprises a hexaazatriphenylene compound.

11. An organic light emitting display device comprising:
a base substrate;
a light emitting element disposed on the base substrate, wherein the light emitting element comprises:
a first electrode;
a light emitting layer disposed on the first electrode, wherein the light emitting layer comprises a light emission host and a light emission dopant; and
a second electrode disposed on the light emitting layer;
a thin film transistor disposed on the base substrate, wherein the thin film transistor is electrically connected to the first electrode of the light emitting element; and
a protective layer disposed on the second electrode of the light emitting element, wherein the base substrate and the protective layer encapsulate the thin film transistor and the light emitting element.

12. The organic light emitting display device of claim 11, wherein
the light emitting layer of the light emitting element has a thickness in a range of about 30 nanometers to about 50 nanometers, and
the light emission host and the light emission dopant of the light emitting layer of the light emitting element are in a weight ratio of about 85:15 to about 90:10.

13. The organic light emitting display device of claim 11, wherein the light emitting element further comprises:
a hole injection layer disposed on the first electrode;
a hole transport layer disposed on the hole injection layer;
a first intermediate layer disposed between the first electrode and the hole injection layer, wherein the first intermediate layer comprises a pyrazine compound;
a second intermediate layer disposed between the hole injection layer and the hole transport layer, wherein the second intermediate layer comprises a hole injection material and a hole transport material;
a third intermediate layer disposed on the hole transport layer, wherein the third intermediate layer comprises the pyrazine compound; and
a host layer disposed on the third intermediate layer, wherein the host layer comprises the light emission host.

14. A method of manufacturing an organic light emitting display device, the method comprising,
providing a thin film transistor on a base substrate of the organic light emitting display device;
providing a first electrode electrically connected to the thin film transistor;
providing a hole injection layer on the first electrode;
providing a hole transport layer on the hole injection layer;
providing a light emitting layer on the hole transport layer, wherein the light emitting layer comprises a light emission host and a light emission dopant;
providing an electron transport layer on the light emitting layer;
providing an electron injection layer on the electron transport layer; and
providing a second electrode on the electron injection layer.

15. The method of claim 14, wherein
the light emitting layer is formed with the light emission host and the light emission dopant by a weight ratio of about 85:15 to about 90:10, and
the light emitting layer has a thickness in a range of about 30 nm to about 50 nm.

16. The method of claim 14, further comprising:
providing a first intermediate layer on the first electrode, using a pyrazine compound, wherein the hole injection layer is provided on the first intermediate layer.

17. The method of claim 16, wherein the pyrazine compound of the first intermediate layer comprises a hexaazatriphenylene compound.

18. The method of claim 16, further comprising:
providing a second intermediate layer on the hole injection layer, wherein the hole transport layer is provided on the second intermediate layer.

19. The method of claim 18, wherein the providing the second intermediate layer on the hole injection layer comprises performing co-deposition or co-sputtering using a hole injection material of the hole injection layer and a hole transport material of the hole transport layer.

20. The method of claim 18, wherein the providing the second intermediate layer on the hole injection layer comprises using a combination of a hole injection material of the hole injection layer and a hole transport material of the hole transport layer.

21. The method of claim 18, further comprising:
providing a third intermediate layer on the hole transport layer, using the pyrazine compound, wherein the light emitting layer is provided on the third intermediate layer.

22. The method of claim 21, wherein the pyrazine compound of the third intermediate layer comprises a hexaazatriphenylene compound.

23. The method of claim 21, further comprising:
providing a host layer on the third intermediate layer, using the light emission host, wherein the light emitting layer is provided on the host layer.
